(19) United States
(12) Patent Application Publication
(10) Pub. No.: US 2001/0002058 A1
(43) Pub. Date: May 31, 2001

(54) Semiconductor apparatus and method of manufacture

(76) Inventor: Ryoichi Nakamura, Tokyo (JP)

Correspondence Address: DARRYL G. WALKER, 4064 BEEBE CIRCLE, SAN JOSE, CA, 95135, US

(21) Appl. No.: 09/726,106

(22) Filed: Nov. 29, 2000

(30) Foreign Application Priority Data
Nov. 30, 1999 (JP) 339577/1999

(51) Int. Cl. H01L 29/00

(52) U.S. Cl. 257/510

(57) ABSTRACT

A semiconductor apparatus (010) is disclosed that includes a gate electrode formed over an active area and isolation area that can address adverse current properties that may result in a subthreshold “hump” in a gate voltage (VG)-drain current (ID) response. A first embodiment (010) may include an active area (016) formed adjacent to an isolation area (018). A gate insulator (014) may be formed over active area (016). A gate electrode (020) can be formed over an active area (016) and an isolation area (018). A gate electrode (020) may include end portions (020a) formed in the vicinity of an active area (016)/isolation area (018) interface, and a central portion (020b) formed between end portions (020a). End portions (020a) may be doped differently than a central portion (020b) to effectively compensate for lower threshold voltages in such areas. End portions (020a) may be doped to a conductivity type that is different than a central portion (020b) and the same as a channel region. Alternatively, end portions (020c) may be doped to a conductivity type that is the same, but lower in concentration than a central portion (020b), and different than a channel region conductivity type.

### TECHNICAL FIELD

The present invention relates generally to the manufacture of semiconductor devices, and more particularly to manufacture of a semiconductor apparatus having a gate electrode formed over an isolation area and an active area.

### BACKGROUND OF THE INVENTION

Continuing advances in semiconductor manufacturing processes have resulted in semiconductor devices with smaller features and higher degrees of integration. In many semiconductor devices, active circuit elements may be formed in active regions and separated from one another by isolation structures.

One previously popular isolation method has included the local oxidation of silicon (LOCOS). LOCOS methods can be undesirable due to the formation of space consuming “birds beak” structures, as well as leakage that can result from mechanical stress introduced in the LOCOS process.

One approach to isolation of increasing popularity is shallow trench isolation (STI). STI can include the formation of a trench in a substrate. Such a trench may then be filled with an isolation dielectric. In this way, trenches may electrically isolate one active area from another.

To better understand the various features of the present invention, a conventional semiconductor structure that includes STI will now be described with reference to FIGS. 6A and 6B. FIG. 6B is top plan view of a conventional semiconductor apparatus that includes a polysilicon gate formed over STI. FIG. 6A is a side cross sectional view of the semiconductor apparatus of FIG. 6B, taken along line VI-VI.

Referring now to FIG. 6A, a conventional semiconductor apparatus 080 may include an active area 016 on which a gate oxide film 014 is formed. An active area 016, in a channel region, may further include portions of a p-well 012 formed in a substrate. An active area 016 may be formed adjacent to shallow trench isolation (STI) 018.

A polysilicon gate electrode 082 may be formed over substrate, including over a gate oxide 014 and STI 018. In the conventional example shown, a polysilicon gate electrode 082 may include dopants that result in the polysilicon of gate electrode 082 being of an n-type conductivity. A tungsten silicide (WSi) gate electrode 024 may be formed over polysilicon gate electrode 082.

Referring now to FIG. 6B, an active area 016 may further include n-type diffusion regions 022 formed in an active area 016, excluding those portions covered by a gate oxide film 014. N-type diffusion regions 022 may form a source and drain of a transistor. A p-type region under a gate oxide film 014 may form a channel.

While a conventional arrangement like that shown in FIGS. 6A and 6B can provide for a compact structure, such an arrangement can have drawbacks. One drawback can include a transistor response. More particularly, a resulting gate voltage (VG) to drain current (ID) response can have undesirable features. Such a conventional response is shown in FIG. 5B.

FIG. 5B is a graph depicting the relationship between the logarithm of a drain current In(ID) and a gate voltage VG. As shown in FIG. 5B, the VG-ID response may include a “hump” shape in a subthreshold region (region below a transistor threshold VT). Such a hump can result in deteriorated transistor cut-off properties.

In light of the above discussion, it would be desirable to arrive at some way of forming a semiconductor apparatus that includes STI and polysilicon gates, but that does not suffer from the drawbacks of a conventional semiconductor apparatus, such as a VG-ID “hump.”

### SUMMARY OF THE INVENTION

Prior to summarizing various embodiments, research related to the present invention will be briefly described.

Research performed on semiconductor apparatuses that include a polysilicon gate and shallow trench isolation (STI) as described above, has pointed to particular causes for the occurrence of a VG-ID hump. It is believed that the application of an electric field by a gate voltage can result in the concentration of an electric field at an STI end of a channel that can reduce a threshold voltage. Such a reduction in threshold voltage is believed to result from two main reasons. First, a semiconductor channel region adjacent to STI is believed to be influenced not only by a polysilicon gate voltage on a gate oxide film, but also from the polysilicon gate voltage on the STI. Such an effect may be particularly acute when a recess portion is formed at an STI end of a channel. Second, a semiconductor channel region adjacent to STI may be more easily inverted as its effective dopant concentration may be lowered by diffusion of impurities toward STI regions.

Because the overall channel area affected by such reductions in threshold voltage is small, when a gate voltage is large with respect to a threshold voltage, the effects can be insignificant. However, when gate voltages are lower than a threshold voltage, portions of a transistor that are ideally turned off, may be turned on. This is believed to cause the undesirable VG-ID hump response. The present invention has been developed based on this information.

According to the present invention, a semiconductor apparatus may include an active area adjacent to an isolation area. A gate insulator may be formed over the active area. A gate electrode can be formed over the active area and isolation area, the active area under the gate electrode including a channel. The gate electrode may include end portions formed in the vicinity of a channel/isolation area interface that are doped differently than a central portion of a gate electrode to compensate for lower threshold voltages in such regions.

According to one aspect of the embodiments, end portions may be doped to the same conductivity type as the channel, which is different than the conductivity type of the central portion. In such an arrangement, the central portion can have an opposite doping with respect to a channel region, resulting in a higher work function difference with respect to a channel. End portions, however, can have the same doping with respect to a channel region, resulting in a lower work function difference with respect to the channel. Thus, end portions may have regions with a higher threshold voltage than central portions.

According to one aspect of the embodiments, end portions may be doped to a different conductivity type than the channel, and the same conductivity type as the central portion. However, the doping concentration of the end portions can be lower than that of the central portion. In such an arrangement, the central portion can have an opposite doping with respect to a channel region, resulting in a higher work function difference with respect to a channel. End portions can have the same doping type as central portions, however, because such doping is at a lower concentration, such an area may have a lower work function difference with respect to the channel. Thus, end portions may have regions with a higher threshold voltage than central portions.

By changing the doping of end portions of a semiconductor gate electrode, higher threshold voltages in such regions can compensate for threshold lowering effects. Such compensation can eliminate and/or reduce adverse transistor responses that may result in a subthreshold “hump” in a gate voltage (VG)-drain current (ID) response.

### BRIEF DESCRIPTION OF THE DRAWINGS

FIGS. 1A and 1B show a semiconductor apparatus according to a first embodiment.

FIGS. 2A to 2C are side cross sectional views showing a method of making the first embodiment.

FIGS. 3A and 3B are side cross sectional view and top plan view further showing a method of making the first embodiment.

FIGS. 4A and 4B are side cross sectional views of a second and third embodiment.

FIGS. 5A and 5B are graphs illustrating the response of one embodiment and the response of a conventional semiconductor apparatus.

FIGS. 6A and 6B show a side cross sectional view and top plan view of a conventional semiconductor apparatus.

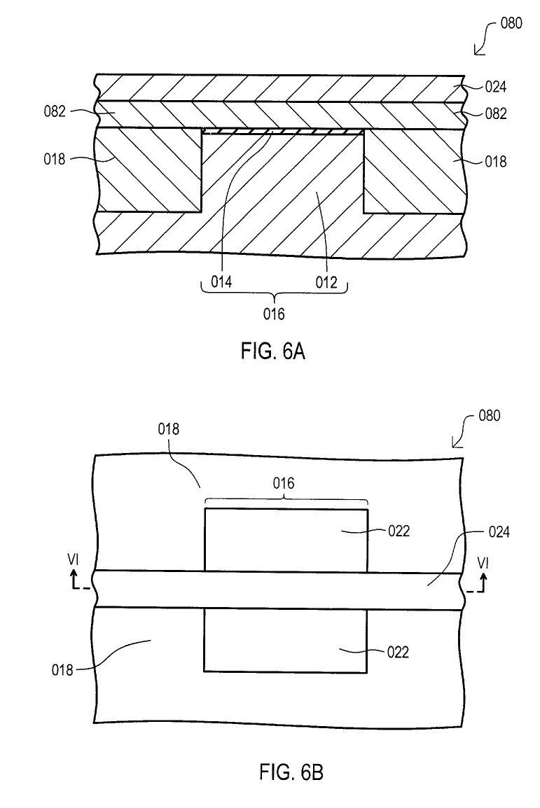

### DETAILED DESCRIPTION OF THE EMBODIMENTS

Various embodiments of the present invention will now be described to in detail with reference to a number of drawings.

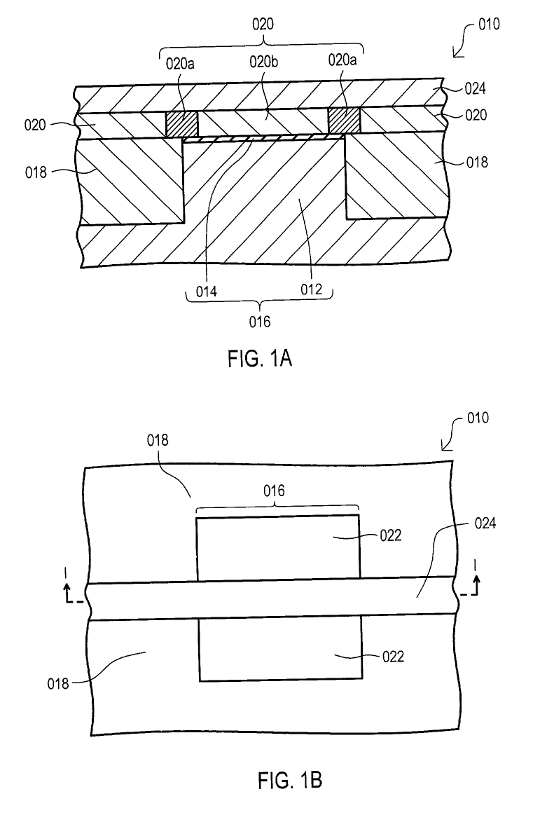

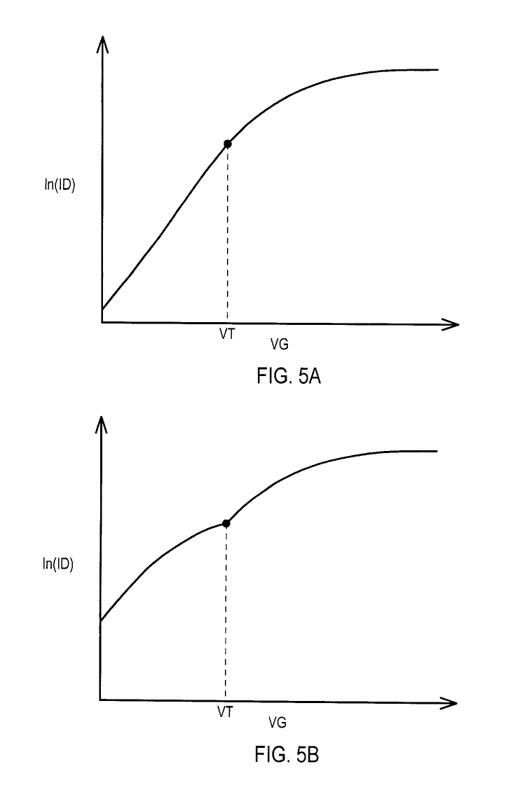

A first embodiment of the present invention will now be described with reference to FIGS. 1A, 1B, and 5A. FIG. 1B is top plan view of a semiconductor apparatus according to a first embodiment, while FIG. 1A is a side cross sectional view of the semiconductor apparatus of FIG. 1B, taken along line I-I. FIG. 5A is a graph depicting the relationship between the logarithm of a drain current In(ID) and a gate voltage VG.

Referring now to FIG. 1A, a conventional semiconductor apparatus 010 may include an active area 016 on which a gate insulator film is formed 014. An active area 016, in a channel region, may further include portions of a p-well 012 formed in a substrate. An active area 016 may be formed adjacent to an isolation area 018. A gate electrode 020 may be formed over substrate, including over a gate insulator 014 and isolation area 018.

An isolation area 018 may be formed with shallow trench isolation (STI).

In a first embodiment, a gate electrode 020 may include a doping arrangement that varies from conventional approaches. In particular, as shown in FIG. 1A, a gate electrode 020 may include end portions 020a and a central portion 020b. End portions 020a may be situated in the vicinity of the channel/isolation area 018 interface and may be doped differently than other portions of a gate electrode 020. Even more particularly, end portions 020a may be doped to a p-type conductivity while remaining portions of a polysilicon gate electrode may be doped to an n-type conductivity.

A conductive alloy gate electrode 024 may be formed over gate electrode 020. In one particular arrangement, a conductive alloy gate electrode 024 may include tungsten silicide (WSi).

Referring now to FIG. 1B, an active area 016 may further include n-type diffusion regions 022 formed in activate area 016 excluding those portions covered by a gate insulator film 014. N-type diffusion regions 022 may form a source and drain of a transistor. A p-type region under a gate insulator film 014 may form a channel.

In a first embodiment 010, the doping type of a p-well 012/channel can be opposite to that of a central portion 020b (n-type), but the same time, can be the same as that of end portions 020a. Further, as is well know, an inversion region formed in a channel by the application of a gate voltage can have an opposite conductivity type as a p-well 012. In such an arrangement, portions of a transistor that include end portions 020a can be conceptualized as having larger threshold voltages than portions of a transistor that include a central portion 020b.

More specifically, since the doping of a central portion 020a can be opposite to a p-well 012/channel, the work function difference between a p-well 012/channel and an n-type gate portion (e.g., a central portion 020a) can be considered large. This can result in a lower threshold voltage. Conversely, since the doping of end portions 020a can be of the same type as a p-well 012/channel, the work function difference between a p-well 012/channel and an p-type gate portion (e.g., end portions 020b) can be considered small. This can result in a higher threshold voltage.

In this way, end portions of a gate electrode may have the same type of doping as a p-well/channel. Such an arrangement can raise threshold voltages in such regions, thereby compensating for a lower threshold voltage due the various reasons described above.

A first embodiment 010 may thus inhibit adverse threshold lowering effects that may produce “hump” in a VG-ID response. Such an effect is shown in FIG. 5A.

FIG. 5A is a graph depicting the relationship between the logarithm of a drain current In(ID) and a gate voltage VG. As shown by comparing FIG. 5A with FIG. 5B, a sub-threshold hump may be absent in a VG-ID response, indicating transistor cut-off properties that are improved with respect to conventional approaches.

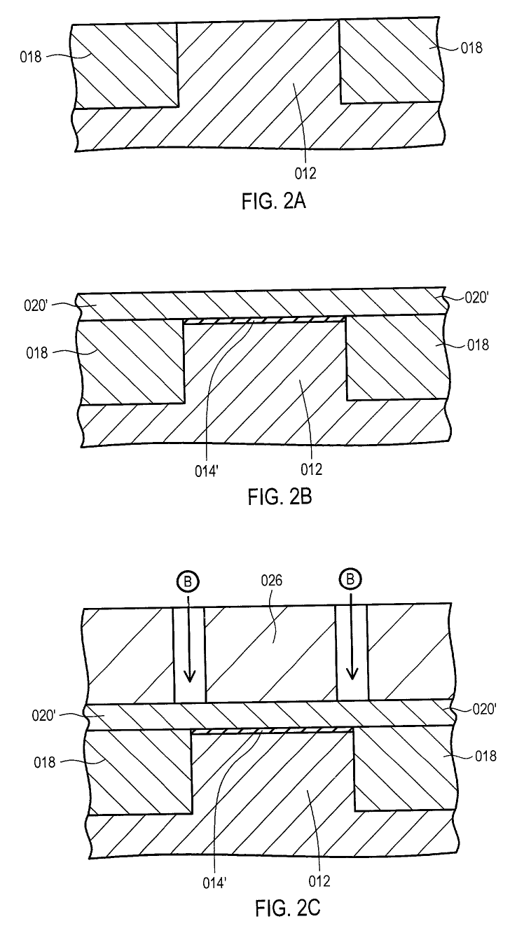

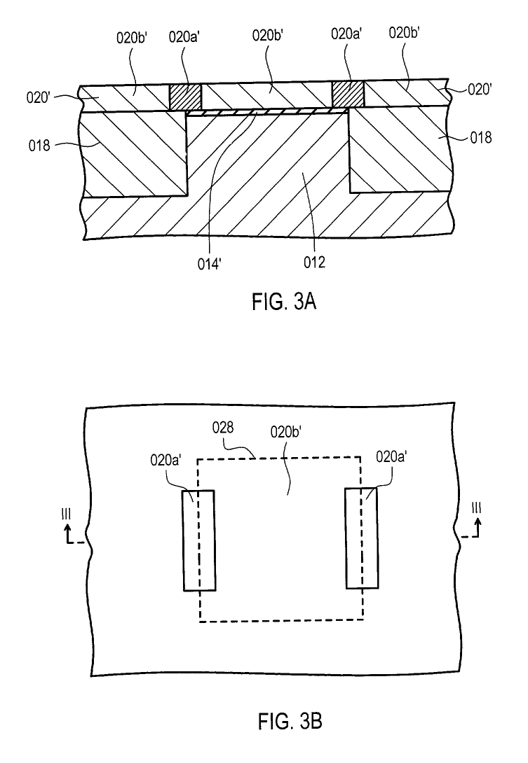

Having described a semiconductor apparatus according to a first embodiment, a method of manufacturing such a semiconductor apparatus will be described with reference to FIGS. 1A and 1B, 2A to 2C, and 3A and 3B. FIGS. 2A to 2C are side cross sectional views of a semiconductor apparatus showing various steps in a manufacturing process. FIG. 3B is a top plan view of semiconductor device showing a particular step in a manufacturing process. FIG. 3A is a side cross sectional view taken along line III-III of FIG. 3B.

Referring now to FIG. 2A, a method of manufacture may include forming isolation areas 018 in a substrate. Such a step may include etching trenches in a substrate to form isolation regions, and subsequently filling such trenches with an insulator. According to one particular approach, isolation area 018 may have a depth in the general range of 300 nm and may be filled with plasma oxide film.

Following the formation of isolation areas 018, a p-type dopant may be introduced into a substrate to form a p-well 012. According to one particular approach, a p-type dopant may include boron that is ion implanted into a substrate. More particularly, boron may be ion implanted in three steps. A first implant step may be at an energy of about 300 keV and a concentration of about 3×10¹³ atoms/cm². A second implant step may be at an energy of about 90 keV and a concentration of about 6×10¹² atoms/cm². A third implant step may be at an energy of about 30 keV and a concentration of about 7×10¹² atoms/cm².

Referring now to FIG. 2B, a gate insulator 014′ may be formed on a substrate (p-well 012). According to one approach, a gate insulator 014′ may be formed by thermal oxidation of a silicon substrate to form an oxide film having a thickness in the general range of 5 nm.

A gate electrode layer 020′ may be formed over a gate insulator 014′ and isolation area 018. A gate electrode layer 020′ may be formed by depositing polycrystalline and/or amorphous silicon (referred to as polysilicon herein) to a thickness of about 100 nm. A gate electrode layer 020′ may be doped with an n-type dopant. In one particular embodiment, a gate electrode layer 020′ may include polysilicon doped with phosphorous at a concentration of 3×10¹⁹ atoms/cm³. In this way, an n-type doped polysilicon film (DOPOS) may be formed.

Referring now to FIG. 2C, masking steps, such as photolithography or the like, may form a mask 026 over a gate electrode layer 020′. A mask 026 may have openings that expose a gate electrode layer 020′ in the vicinity of channel/isolation area 018 interfaces. In one particular arrangement, a mask 026 may be formed from photoresist.

Subsequently, portions of a gate electrode layer 020′ exposed by a mask 026 may be doped to a different conductivity type than portions of a gate electrode layer 020′ covered by a mask 026. In one particular arrangement, exposed portions of an n-type gate electrode layer 020′ may be oppositely doped by ion implanting a p-type dopant. In one particular arrangement, boron can be ion implanted at an energy of about 5 keV and a concentration of about 2×10¹⁵ atoms/cm². In this way, regions of a gate electrode layer 020′ in the vicinity of a channel/isolation region 018 boundary can be changed from n-type doping to p-type doping.

A mask 026 may then be removed.

Referring now to FIG. 3A, an example of a semiconductor apparatus following the removal of a mask 026 is shown in a side cross sectional view. As shown in FIG. 3A, a gate electrode layer 020′ may include differently doped portions. In particular, n-type portions are shown as 020b′ while p-type portions are shown as 020a′. Thus, a semiconductor apparatus may be conceptualized as including an n-type DOPOS film and a p-type DOPOS film.

Referring now to FIG. 3B, a semiconductor apparatus following removal of a mask 026 is shown in a top plan view. FIG. 3B shows p-type regions 020a′ and n-type regions 020b′. In addition, a dashed line 028 denotes a p-well 012/isolation region 018 boundary.

Referring back to FIG. 1A, a conductive alloy layer may be formed over a gate electrode layer 020′. In one arrangement, a conductive alloy layer may include WSi. A gate electrode layer 020′ and conductive alloy layer may then be patterned to form a gate electrode 020 and conductive alloy gate electrode 024 as set forth in FIG. 1A. In one arrangement, such a patterning step may include lithography and etch steps.

A method of forming a semiconductor apparatus may continue with various doping steps to form particular transistor structures. In one particular arrangement, an n-type dopant may be used to form lightly doped drain (LDD) type regions. More particularly, phosphorous may be ion implanted with a gate electrode 020 and conductive alloy gate electrode 024 as implant masks. Sidewall spacers may then be formed on the sides of gate electrodes 020 and conductive alloy gate electrode 024. Another n-type dopant may then be used to form source/drain regions. More particularly, arsenic may be ion implanted with a gate electrode 020, conductive alloy gate electrode 024, and sidewalls functioning as an implant mask.

Implanted ions may then be activated with an anneal step. An interlayer insulating film may then be formed over a substrate. A contact may then be formed through such a interlayer insulating film. In one particular arrangement, forming a contact may include etching a contact hole, filling a contact hole with a conductive plug, and then connecting a wiring layer to the plug.

In this way, a semiconductor apparatus may be formed that includes a polysilicon gate and STI, but may have a transistor response that is improved over conventional approaches.

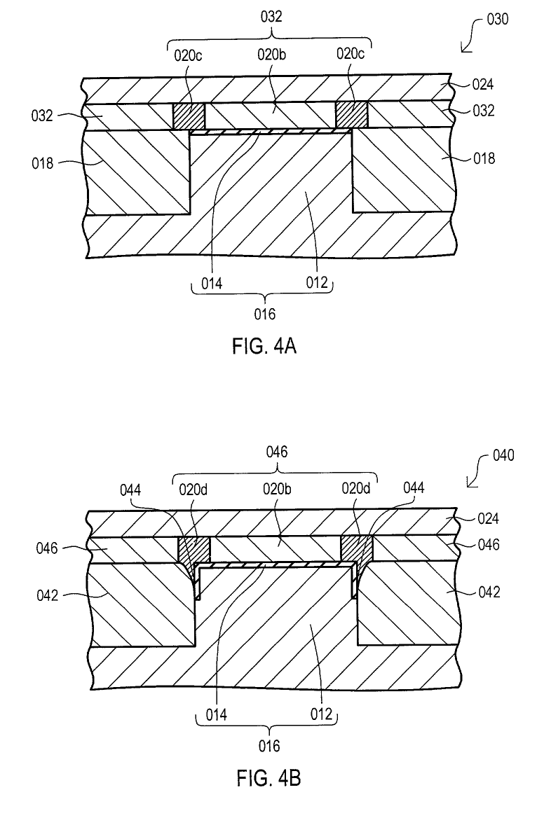

A second embodiment will now be described with reference to FIG. 4A. FIG. 4A is a side cross sectional view of a semiconductor apparatus 030. A semiconductor apparatus 030 may include some the same general constituents as the first embodiment 010 shown in FIG. 1A. To that extent, like portions will be referred to by the same reference characters.

A semiconductor apparatus 030 according to a second embodiment may include a gate electrode 032 formed on a gate insulator 014 and isolation area 018. A gate electrode may include end portions 020c that are formed in the vicinity of a p-well 012/channel interface, as well as a central portion 020b between end portions 020c. End portions 020c and a central portion 020b may be doped to the same conductivity type (e.g., n-type). However, end portions 020c may have a lower doping concentration than a central portion 020b.

In one particular arrangement, end portions 020c may be formed in the same general fashion as p-type regions 020a′ of FIG. 3A. However, the amount of boron implanted can be decreased. Thus, lower n-type doped end portions 020c may be easier to form than p-type end portions 020a.

In a second embodiment 030, the doping type of a p-well 012/channel can be opposite to that of a central portion 020b and end portions 020c (which are both n-type), with end portions 020c having a lower concentration than a central portion 020b. Further, as is well known, an inversion region formed in a channel by the application of a gate voltage can have an opposite conductivity type as a p-well 012. In such an arrangement, portions of a transistor that include end portions 020c can be conceptualized as having larger threshold voltages than portions of a transistor that include a central portion 020b.

More specifically, since the doping of a central portion 020b can be opposite to a p-well 012/channel, the work function difference between a p-well 012/channel and an n-type gate portion (e.g., a central portion 020b) can be considered large. This can result in a lower threshold voltage. However, while end portions 020c may have the same doping type as central portion 020b, such doping can be lower in concentration. Thus, the work function difference between a p-well 012/channel and a lower doped n-type gate portion (e.g., end portions 020c) can be considered smaller. This can result in a higher threshold voltage.

In this way, end portions of a gate electrode may have a lower doping than other portions of a gate electrode. Such an arrangement can raise threshold voltages in such locations, thereby compensating for a lower threshold voltage due the various reasons described above.

A second embodiment 030 may thus inhibit adverse threshold lowering effects that may produce a “hump” in a VG-ID response.

A third embodiment with now be described with reference to FIG. 4B. FIG. 4B is a side cross sectional view of a semiconductor apparatus 040. A semiconductor apparatus 040 may include some of the same general constituents as the first embodiment 010 shown in FIG. 1A. To that extent, like portions will be referred to by the same reference characters.

A semiconductor apparatus 040 according to a third embodiment may include recess portions 044. A recessed portion 044 may be formed in STI 042 in regions adjacent to an active area 016. Recess portions 044 may be produced unintentionally in a STI isolation region 042 formation process.

Conventionally, the formation of recess portions 044 may further increase electric field concentration resulting from a gate voltage under end portions 020d. This can further contribute to undesirably high currents and subthreshold gate voltages.

The present invention may address such conventional drawbacks by including end portions 020d that are oppositely doped, or lower doped than a central portion 020b. Such an arrangement can raise threshold voltages in such recess portions 044, thereby compensating for a lower threshold voltage. A third embodiment 040 may thus inhibit adverse threshold lowering effects from recess portions 044 that may produce and/or contribute to a “hump” in a VG-ID response.

It is understood that while the various embodiments have described semiconductor apparatuses that may be included in n-type insulated gate field transistors (IGFETs), such teachings may be applied to p-channel IGFETs. In the case of p-channel IGFETs, doping types may be opposite to those of an n-type IGFET, as is well understood in the art.

Still further, the various materials and numeric ranges described are provided by way of particular examples of embodiments, and should not be necessarily construed as limiting the invention thereto.

Along these same lines, particular described structures should not be construed as limiting to the invention. As but one example, while the teachings set forth herein may be highly desirable in structures that include STI, such techniques may be employed in conjunction with other isolation techniques, such as LOCOS.

The various embodiments have described a semiconductor apparatus and method of manufacture in which a gate electrode may include end portions formed in the vicinity of a channel/isolation interface. Such end portions may have the same conductivity type doping as a channel region and/or may be oppositely doped, but at a lower concentration than other portions of gate electrode. Such an arrangement can essentially raise the threshold voltage at such interface regions, thereby compensating for a lowering of threshold voltages that may generate an undesirable hump in a transistor VG-ID response.

The present invention may address adverse “hump” responses in apparatuses that include a gate electrode formed over STI. Further, the present invention may address such hump responses that may arise due to recess portions formed at a channel/isolation interface.

While the various particular embodiments set forth herein have been described in detail, the present invention could be subject to various changes, substitutions, and alterations without departing from the spirit and scope of the invention. Accordingly, the present invention is intended to be limited only as defined by the appended claims.

What is claimed is:

1. A semiconductor apparatus, comprising:
an active area adjacent to an isolation area at an active area/isolation area interface;
a gate insulator formed over the active area; and
a gate electrode formed over the gate insulator and isolation area that includes a central portion and an end portion in the vicinity of the active area/isolation area interface; wherein
the active area below the gate electrode is doped to a first conductivity type and the central portion is doped to a second conductivity type, and the end portion is doped differently than the central portion.

2. The semiconductor apparatus of claim 1, wherein:
the end portion is doped to the first conductivity type.

3. The semiconductor apparatus of claim 1, wherein:
the end portion is doped to the second conductivity type at a lower concentration than the central portion.

4. The semiconductor apparatus of claim 1, wherein:
the isolation area includes shallow trench isolation.

5. The semiconductor apparatus of claim 1, wherein:
the first conductivity type is p-type and the second conductivity type is n-type.

6. The semiconductor apparatus of claim 1, wherein:
the first conductivity type is n-type and the second conductivity type is p-type.

7. A semiconductor apparatus, comprising:
a semiconductor gate electrode having threshold raising doping at an end portion formed over a channel-isolation interface that is different than a doping of a central portion formed over the channel.

8. The semiconductor apparatus of claim 7, wherein:
the threshold raising doping includes a doping of a first conductivity type that is the same as a channel conductivity type.

9. The semiconductor apparatus of claim 7, wherein:
the threshold raising doping includes a doping of a lower concentration and the same conductivity type as the doping of the central portion.

10. The semiconductor apparatus of claim 7, wherein:
the channel-isolation interface includes a recessed portion in the channel.

11. The semiconductor apparatus of claim 7, wherein:
the gate electrode comprises polysilicon.

12. The semiconductor apparatus of claim 7, further including:
the channel is doped to a first conductivity type;
the central portion is doped to a second conductivity type; and
source and drain regions formed adjacent to the channel that are doped to the second conductivity type.

13. The semiconductor apparatus of claim 7, wherein:
the isolation includes shallow trench isolation comprising trenches etched in a substrate and filled with an insulating material.

14. A method of forming a semiconductor apparatus, comprising the steps of:
forming a semiconductor gate layer; and
doping at least one end portion of the semiconductor gate layer differently than other portions of the gate layer, the at least one end portion being formed in the vicinity where an active area is adjacent to an isolation area.

15. The method of claim 14, wherein:
forming a semiconductor gate layer includes depositing a layer of polysilicon over the active area and the isolation area.

16. The method of claim 14, wherein:
doping at least one end portion includes
forming a mask over the semiconductor gate layer having an opening over the at least one end portion, and
implanting ions.

17. The method of claim 16, wherein:
implanting ions includes implanting ions of a first conductivity type into exposed portions of a semiconductor gate layer that is doped to a second conductivity type.

18. The method of claim 14, wherein:
doping at least one end portion includes changing the conductivity type of the at least one end portion.

19. The method of claim 14, wherein:
doping at least one end portion includes lowering the concentration of the at least one end portion with respect to other portions of the semiconductor gate layer.

20. The method of claim 14, further including:
forming the isolation area with shallow trench isolation.
